(19) United States
(12) Patent Application Publication
(10) Pub. No.: US 2023/0167537 A1
(43) Pub. Date: Jun. 1, 2023

(54) METAL MASK, EVAPORATION METHOD, DISPLAY PANEL AND DISPLAY DEVICE

(71) Applicants: MIANYANG BOE OPTOELECTRONICS TECHNOLOGY CO.,Ltd., Mianyang, Sichuan (CN); BOE Technology Group Co., Ltd., Beijing (CN)

(72) Inventors: Hsinju HO, Beijing (CN); Guangjin LI, Beijing (CN); Qingyang DING, Beijing (CN); Honglin PENG, Beijing (CN); Yongshan FENG, Beijing (CN)

(21) Appl. No.: 17/922,785

(22) PCT Filed: Jul. 5, 2021
(86) PCT No.: PCT/CN2021/104509

§ 371 Date: Nov. 1, 2022

(30) Foreign Application Priority Data
Aug. 4, 2020 (CN) 202010774713.9

(51) Int. Cl. C23C 14/04; G03F 9/00; C23C 14/24

(52) U.S. Cl. CPC C23C 14/042; C23C 14/24; G03F 9/7076

(57) ABSTRACT

A metal mask includes: a metal frame, the metal frame being provided with a hollow region; and an alignment metal strip, the alignment metal strip being located at the edge of one side of the metal frame and being provided with a first align mark and a first photographing mark. The first align mark and the first photographing mark are arranged in the extending direction of the edge, the metal frame is provided with a first hole, and an orthographic projection of the first photographing mark on the metal frame is located within the area in which the first hole is located.

### CROSS-REFERENCE TO RELATED APPLICATIONS

This application is a national stage application of PCT Application No. PCT/CN2021/104509, which is filed on Jul. 05, 2021 and claims the priority to the Chinese patent application No. 202010774713.9, entitled “Metal Mask, Evaporation Method, Display Panel and Display Device”, filed to the CNIPA on Aug. 04, 2020, the content of which should be regarded as being incorporated herein by reference.

### TECHNICAL FIELD

The present application relates to the field of display, in particular to a metal mask, an evaporation method, a display panel, and a display device.

### BACKGROUND

For a present display panel, a material such as an emitting layer in an Organic Light Emitting Device (OLED) display panel needs to be formed on a display substrate by means of evaporation with help of a mask. However, in an existing evaporation device, alignment between a display substrate and a mask is achieved by identifying and matching an align mark (Mark) on a metal mask and an align mark exposed on the substrate. Specifically, the mask and the display substrate may be aligned by identifying the two align marks through a Charge Coupled Device (CCD) with a light source. However, an align mark based on a metal bottom has a poor identification degree under a CCD with a light source.

Therefore, a current metal mask and evaporation method, display panel, and display device still need to be improved.

### SUMMARY

The present application aims at alleviating or solving at least one of the above mentioned problems at least to some extent.

In one aspect of the present application, the present application provides a metal mask. The metal mask includes: a metal frame, wherein the metal frame is provided with a hollow region; an alignment metal strip, wherein the alignment metal strip is located at an edge of one side of the metal frame, a first align mark and a first photographing mark are provided on the alignment metal strip, and the first align mark and the first photographing mark are arranged along a direction in which the edge extends, the metal frame is provided with a first hole, and an orthographic projection of the first photographing mark on the metal frame is located in a region where the first hole is located. Therefore, a gray tone contrast ratio of the first photographing mark under a CCD may be improved by using the first hole, thereby being beneficial to improving align accuracy of the metal mask.

According to the embodiment of the present application, the first hole is an inclined hole and penetrates through the metal frame, and an included angle between the inclined hole and a plane where the metal frame is located is 10-80 degrees. Thus, a material to be evaporated may be prevented from being deposited on a substrate to be evaporated through the first hole on a premise of improving a contrast ratio of the first photographing mark.

According to the embodiment of the present application, the orthographic projection of the first photographing mark on the metal frame is located in a region of a first opening of the first hole, and the first opening is an opening of the first hole on a side surface of the metal frame facing the alignment metal strip. Therefore, align accuracy of the metal mask may be further improved.

According to the embodiment of the present application, the first align mark and the first photographing mark are hollow patterns on a metal. Therefore, the first align mark and the first photographing mark may be easily obtained.

According to the embodiment of the present application, shapes of the first align mark and the first photographing mark are different, and directions, extending along the edge, of the first align mark and the first photographing mark are located on a same straight line. Therefore, align accuracy of the metal mask may be further improved.

According to the embodiment of the present application, the metal frame is further provided with a second hole, wherein the second hole is located at an orthographic projection of the first align mark on the metal frame, and the second hole is an inclined hole. Therefore, align accuracy of the metal mask may be further improved.

According to the embodiment of the present application, the first align mark and the first photographing mark each have a symmetry center and at least one symmetry axis, and a symmetry center of the first align mark is located on a straight line where a symmetry axis of the first photographing mark is located. Therefore, align accuracy of the metal mask may be further improved.

According to the embodiment of the present application, the first photographing mark is rectangular, the first align mark is circular, and the first hole is a round hole. Therefore, align accuracy of the metal mask may be further improved.

In another aspect of the present application, the present application provides a method of evaporation using the metal mask described above. The method includes: moving a substrate to be evaporated above the metal mask, wherein the substrate is provided with a first substrate mark having a same shape as the first align mark of the metal mask, and a second substrate mark corresponding to the first photographing mark; while making the first align mark align with the first substrate mark, make a position of an orthographic projection of the second substrate mark on the metal mask cover the first photographing mark, to make the metal mask and the substrate implement alignment; and evaporating a material to be evaporated on the substrate based on the aligned metal mask. This method may easily and accurately achieve alignment of the metal mask and the substrate.

According to the embodiment of the present application, making the metal mask and the substrate implement alignment includes: capturing an image of the second substrate mark using a charge coupled device, and determining a position of the second substrate mark depending on gray tone recognition, to implement the alignment based on the second substrate mark and the first align mark. Therefore, alignment of the metal mask and the substrate may be easily achieved.

In another aspect of the present application, the present application provides a display panel. The display panel is prepared using the metal mask described above. Therefore, the display panel has at least one of advantages of high align accuracy and the like.

In another aspect of the present application, the present application provides a display device. The display device includes the display panel described above. Therefore, the display device has all features and advantages of the display panel described above, which will not be repeated here.

### BRIEF DESCRIPTION OF DRAWINGS

The above mentioned and/or additional aspects and advantages of the present application will become apparent and easy to understand from the following description of embodiments in conjunction with accompanying drawings.

FIG. 1 shows a schematic diagram of a structure of a metal mask according to an embodiment of the present application.

FIG. 2 shows a cross-sectional schematic diagram of a partial structure of a metal mask according to an embodiment of the present application.

FIG. 3 shows a schematic diagram of a partial structure of a metal mask according to an embodiment of the present application.

FIG. 4 shows a schematic diagram of a partial structure of a metal mask according to an embodiment of the present application.

FIG. 5 shows a schematic diagram of a partial structure of a metal mask according to an embodiment of the present application.

FIG. 6 shows an electronic photograph of a CCD capturing an align mark on a metal mask according to an embodiment of the present application.

### DETAILED DESCRIPTION

Descriptions will now be made in detail to embodiments, illustrations of which are shown in the accompanying drawings. The same or similar, or functionally same or similar elements are indicated by like reference numerals throughout the descriptions. The embodiments described herein with reference to the accompanying drawings are exemplary, used for explaining the present disclosure only, and should not be construed to limit the present application.

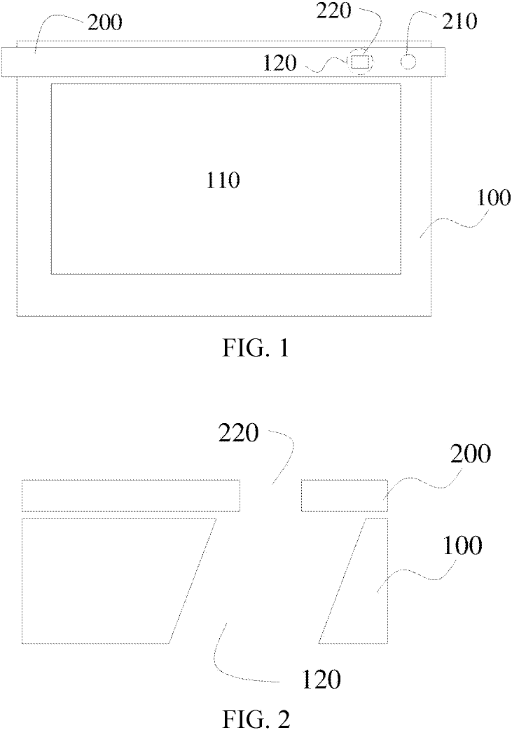

In one aspect of the present application, the present application provides a metal mask. Referring to FIG. 1, the metal mask includes a metal frame 100 and an alignment metal strip 200, wherein the metal frame 100 is provided with a hollow region 110 so that a material to be evaporated may be evaporated onto a substrate to be evaporated through the hollow region 110. The alignment metal strip 200 is located at an edge of one side of the metal frame, and a first align mark 210 and a first photographing mark 220 are provided on the alignment metal strip 200 and are arranged along a direction in which an edge of the metal frame extends. Referring to FIG. 2, the metal frame is provided with a first hole 120 (shown in FIG. 1 in a dashed line) and an orthographic projection of the first photographing mark 220 on the metal frame is located in a region of the first hole 120. Therefore, a gray tone contrast ratio of the first photographing mark under a CCD may be improved by using the first hole, thereby being beneficial to improving align accuracy of the metal mask.

It should be especially noted here that the hollow region 110 in the drawings of the present application is only for illustrating a position of a hollow region, and cannot be understood as limiting a specific shape and quantity of the hollow region of the metal mask according to the embodiment of the present application.

For convenience of understanding, a principle that the metal mask may achieve the above beneficial effects is briefly explained below.

As mentioned above, alignment of a current metal mask is usually achieved through an align mark on a mask and an align mark on a substrate to be evaporated. However, due to a relatively high reflectivity of the metal mask, the metal mask reflects light seriously under irradiation of a CCD, especially the CCD with its own light source, which affects determination of a position of the align mark on the substrate to be evaporated. Specifically, the mask usually has a region corresponding to the mark on the substrate to be evaporated, such as a region where the first photographing mark as described above in the present application is located, and the position of the align mark on the substrate to be evaporated may be observed in this region during an alignment process, thereby achieving alignment. Especially when the CCD determines a boundary of an align mark according to a captured gray level of an align mark on a metal mask, reflection of light will greatly reduce a contrast ratio of the field of view of the CCD, and then lead to inaccurate determination of the boundary of the align mark on the substrate to be evaporated. The metal mask according to the embodiment of the present application may improve a contrast ratio of the first photographing mark under the field of view of the CCD, by adding the first hole on the metal frame corresponding to the first photographing mark. Therefore, accuracy of determining the boundary of the align mark on the substrate may be improved, and further align accuracy of the metal mask may be improved.

According to the embodiment of the present application, the metal mask is used for defining an evaporation region for a material to be evaporated when preparing a display panel. For convenience of understanding, an alignment process during evaporation using the metal mask is briefly described below. According to an embodiment of the present application, a substrate to be evaporated has a first substrate mark corresponding to a first align mark and a second substrate mark corresponding to a position where a first photographing mark is located. A position of the metal mask may be determined by aligning the first align mark, the first photographing mark, and substrate marks on an evaporated substrate. Specifically using a single align mark does not accurately position the metal mask in X and Y directions of a plane on which the substrate to be evaporated is located. An alignment metal strip according to the embodiment of the present application is provided with a first align mark and a first photographing mark. Therefore, the first align mark may be used for aligning with the first substrate mark on the substrate to be evaporated, and a position of the first align mark is a position of an align mark on the substrate. At the same time, the first photographing mark corresponds to the second substrate mark on the substrate, so that a position of the metal mask may be determined in the X and Y directions according to the first photographing mark and the first align mark on the substrate. The metal frame may further have a second hole, and the second hole is located at an orthographic projection of the first align mark 210 on the metal frame. That is to say, the metal frame has a second hole corresponding to the first align mark 210 on the alignment metal strip, and the second hole may also be an inclined hole. Therefore, align accuracy may be further improved.

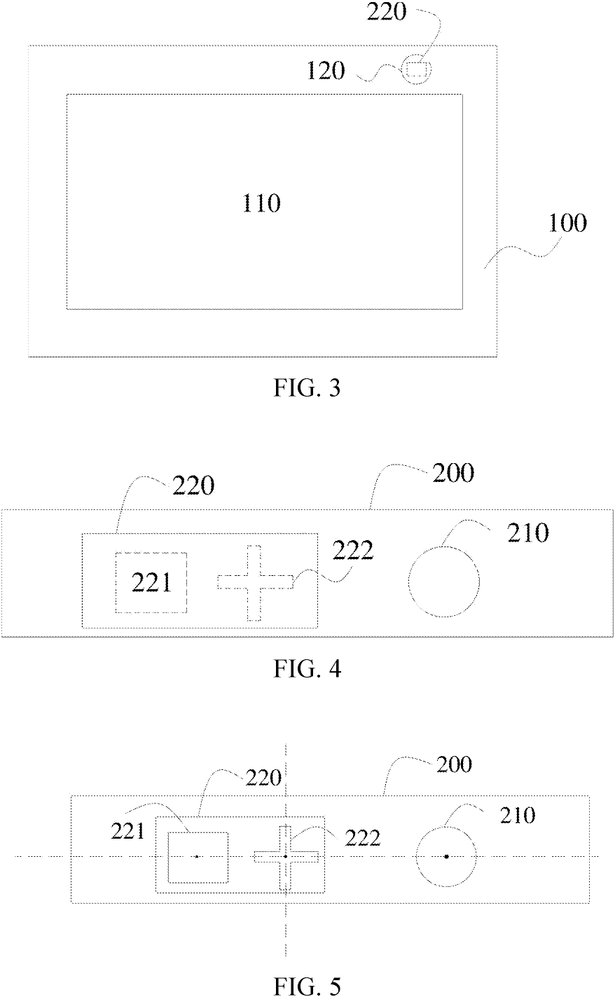

According to some embodiments of the present application, referring to FIGS. 2 and 3, in order to further improve an effect of evaporation using the metal mask, the first hole 120 may be an inclined hole and penetrate through the metal frame 100. Thus, a material to be evaporated may be prevented from being deposited on the substrate to be evaporated through the first hole 120 on a premise of improving a contrast ratio of the first photographing mark 220. That is to say, the first hole 120 may be an inclined hole having an included angle with a thickness direction of the metal frame 100. According to a specific embodiment of the present application, an included angle between the inclined hole and a plane where the metal frame is located may be 10-80 degrees. Thereby, a material to be evaporated is not deposited on the substrate to be evaporated through a gap between the first hole and the first photographing mark. As described above, in the present application, the first hole 120 is used for reducing metallic reflection around the second alignment 220 mark and improving its contrast ratio under a CCD or another element. Therefore, an area of the first hole 120 needs to be larger than an area of the first photographing mark 220. That is, an orthographic projection of the first photographing mark 220 on the metal frame 100 needs to fall within an opening range of the first hole 120. Thus, an entire boundary of the second substrate mark corresponding to the first photographing mark 220 can be clearly captured by the CCD. According to a specific embodiment of the present application, when the first hole 120 is an inclined hole, the orthographic projection of the first photographing mark 220 on the metal frame may be located in a region of a first opening of the first hole 120, specifically, the first opening may be an opening of the first hole on a side surface of the metal frame facing the alignment metal strip. Therefore, align accuracy of the metal mask may be further improved.

According to the embodiment of the present application, specific shapes and forming modes of the first align mark 210 and the first photographing mark 220 are not particularly limited, and those skilled in the art may choose according to an actual situation and requirements of a processing technology. For example, the first align mark and the first photographing mark may be hollow patterns on a metal. Thus, the first align mark and the first photographing mark may be easily obtained by punching holes in corresponding positions of the metal frame and the alignment metal strip. Shapes of the first align mark 210 and the first photographing mark 220 are different, and directions, extending along an edge, of the first align mark and the first photographing mark may be located on a same straight line. Therefore, align accuracy may be further improved. As described above, the substrate to be evaporated has a substrate mark corresponding to the first photographing mark 220, and since the first hole is provided on the metal frame at the second align mark 220, a difference in a shape of the first photographing mark 220 and a shape of the first align mark 210 facilitates distinguishing different mark regions. In addition, directions, extending along an edge, of the first align mark and the first photographing mark may be located on a same straight line, and alignment between the mask and the substrate may be achieved more conveniently, that is, moving directions in an alignment process may only be an X direction and a Y direction that are vertical.

It should be especially noted here that directions, extending along the edge, of the first align mark and the first photographing mark may be located on the same straight line, which should be understood in a broad sense, that is, centerlines of the two may be located on a same straight line, and the straight line may be a straight line parallel to an edge of the metal frame.

According to the embodiment of the present application, in order to further improve an effect of evaporation using the metal mask, referring to FIGS. 4 and 5, an area of the first photographing mark 220 is larger than an area of the second substrate mark on the substrate to be evaporated. Therefore, align accuracy of the metal mask may be further improved. Specifically, taking a case in which the second substrate mark has two sub-marks (221 and 222 as shown in the figure), one of which is in a shape of a rectangle and the other is in a shape of a cross, as an example, both the rectangle and the cross have symmetry axes, and one centerline of the rectangle (that is, a straight line where centerlines of two opposite sides are located) and a centerline of one cross side of the cross may be located on a same straight line (referring to a dashed line shown in FIG. 5). Therefore, when performing alignment using the two sub-marks, a position of the metal mask may be adjusted by using edges of the rectangle and the cross. Specifically, when the metal mask and the substrate to be evaporated are aligned, a projection of the first photographing mark 220 on the substrate to be evaporated is located at the two sub-marks, so that a contrast ratio of the two sub-marks on the substrate under the field of view of the CCD may be improved through the hollowed-out first photographing mark, further a boundary of the two sub-marks may be captured more accurately. By capturing edges of a rectangular mark and a cross-shaped mark, positions of a centerline of the rectangle and a centerline of one cross side of the cross may be confirmed. A position of the metal mask in the X direction may be confirmed by using a straight line where the centerline of the rectangle is located. A position of the metal mask in the Y direction may be confirmed depending on the other cross side (perpendicular to the centerline) of the cross. Therefore, an alignment situation of the metal mask may be confirmed more accurately.

It should be especially noted herein that the rectangular sub-mark and the cross-shaped sub-mark described above are only one embodiment according to the present application and should not be construed as limiting a specific shape of an align mark of the present application. Similarly, the first align mark shown in the drawings may be denoted as in a shape of a circle and the first hole is a round hole, which are only specific shapes according to one example of the present application, and should not be construed as limitations on shapes of the first align mark and the first hole. Those skilled in the art may understood that confirmation of positions of the metal mask in the X direction and the Y direction may be achieved as long as the first photographing mark may improve a degree of clarity of boundary identification of the second substrate mark on the substrate to be evaporated. For example, the first align mark and the second substrate mark may each have a symmetry center and at least one symmetry axis. Thereby, symmetry centers of the second substrate mark having multiple sub-marks and the first align mark may be located on a same straight line (as shown in FIG. 5), to confirm positioning of the metal mask in the X or Y direction, and to confirm positioning of the metal mask in the other direction through a symmetry axis of the multiple sub-marks (such as perpendicular to a straight line where a symmetry center of multiple marks is located). Preferably, a symmetry center of the first align mark may be located on a straight line where one symmetry axis of the second substrate mark is located. Therefore, align accuracy of the metal mask may be further improved. More preferably, the second substrate mark may be located at a position of a center of the first photographing mark. Therefore, a shape and an area of the first photographing mark may be confirmed according to a shape and a position of the second substrate mark on the substrate to be evaporated, so as to ensure that all boundaries of the second substrate mark may be captured by the CCD through the first photographing mark during an alignment process.

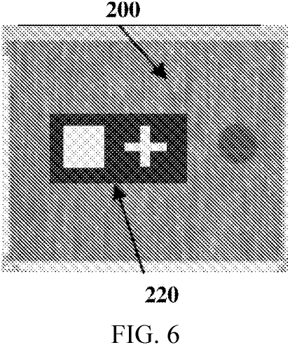

In general, the metal mask according to the embodiment of the present application may alleviate a defect that a boundary of a mark on the substrate to be evaporated in the field of view of the CCD is not easy to be identified, caused by the first photographing mark due to reflection of a metal material. When a shape of an align mark on the alignment metal strip is as shown in FIG. 4, an electronic photograph of the align mark in the field of view of the CCD is referred to FIG. 6. As may be seen from FIG. 6, at this time, due to an action of the first hole (not shown in the figure), there is no metal reflection around the first photographing mark 220, and an image contrast ratio is relatively large, a boundary of the first photographing mark 220 and sub-marks (rectangle and cross) of two second substrate marks on the substrate to be evaporated may be clearly observed in a gray-level mode.

In another aspect of the present application, the present application provides a method of evaporation using the metal mask described above. According to an embodiment of the present application, the method includes: moving the substrate to be evaporated above the metal mask, and the substrate is provided with a first substrate mark having a same shape as a first align mark of the metal mask, and a second substrate mark corresponding to a first photographing mark. While making the first align mark align with the first substrate mark, a position of an orthographic projection of the second substrate mark on the metal mask is made to cover the first photographing mark, so as to make the metal mask and the substrate implement alignment. After the metal mask and the substrate are aligned, a material to be evaporated may be evaporated on the substrate by using an evaporation device. This method may easily and accurately achieve alignment of the metal mask and the substrate.

Those skilled in the art can understand that the substrate to be evaporated is usually a glass plate and therefore has a certain light transmittance. The second substrate mark on the glass substrate may be white. Thus, on one hand, when the substrate to be evaporated is moved above the metal mask, the first photographing mark on the metal mask in the field of view of the CCD may serve as a photographing background of the second substrate mark, so as to capture a boundary of the second substrate mark.

According to an embodiment of the present application, making the metal mask and the substrate implement alignment includes: capturing an image of the second substrate mark using a charge coupled device, and determining a position of the second substrate mark depending on gray tone recognition, so as to implement alignment based on the second substrate mark and the first align mark. Therefore, alignment of the metal mask and the substrate may be easily achieved. Specifically, a substrate mark on the substrate to be evaporated may first be aligned with the first align mark and a first frame mark, at this time, the first photographing mark is also located above the second substrate mark. Subsequently, a position of a center of the second substrate mark may be calculated by capturing an image of the second substrate mark in the field of view of the CCD. When the second substrate mark is provided with multiple sub-marks, center positions of the multiple sub-marks may be calculated simultaneously. As mentioned above, when the substrate to be evaporated and the metal mask are aligned, the first photographing mark is located in a region where the second substrate mark is located. At this time, since the metal frame under the first photographing mark is provided with a first hole, the first photographing mark is darker than a color of a surrounding metal alignment strip in the field of view of the CCD. Therefore, a dark photographing background may be provided for the second substrate mark on the substrate to be evaporated, thereby improving a clarity degree of the second substrate mark under the field of view of the CCD. Then, the metal mask or the substrate to be evaporated is moved to make a center position of the second substrate mark coincide with a predetermined position, so as to achieve alignment of the metal mask. It should be especially noted herein that a sequence of alignment of the first align mark and the first photographing mark is not particularly limited and may be selected according to an actual situation by those skilled in the art. Since the aforementioned metal mask is adopted in this method, a contrast ratio in the field of view of the CCD is better when a position of the second substrate mark is collected, and a position of a boundary of the second substrate mark is determined more accurately, so that a product yield of a display panel prepared by this method may be improved.

In another aspect of the present application, the present application provides a display panel. The display panel is prepared using the metal mask described above. Therefore, the display panel has at least one of advantages of high align accuracy and the like.

In another aspect of the present application, the present application provides a display device. The display device includes the display panel described above. Therefore, the display device has all features and advantages of the display panel described above, which will not be repeated here.

In the description of the present application, an orientation or a positional relationship indicated by terms “up”, “down”, etc. is based on an orientation or a positional relationship shown in the drawings, and is only for convenience of describing the present application without requiring the present application to be constructed and operated in a specific direction, and therefore cannot be understood as a limitation on the present application.

In the description of this specification, description referring to terms “one embodiment”, “another embodiment”, etc. means that specific features, structures, materials, or characteristics described in connection with this embodiment are contained in at least one embodiment of the present application. In this description, the schematic expression of the above terms does not necessarily refer to the same embodiment or example. Moreover, the specific feature, structure, material, or characteristic described may be combined in a proper way in any one or more embodiments or examples. In addition, without a conflict, a person skilled in the art may combine different embodiments or examples described in this description and the features of different embodiments or examples.

Although the embodiments of the present application have been shown and described above, it should be understood that the above embodiments are exemplary, and will not be understood as the limitation to the present application. Alterations, modifications, substitutions and variations to the above embodiments may be made by those skilled in the art within the scope of the present application.

1. A metal mask, comprising:
a metal frame, wherein the metal frame is provided with a hollow region;
an alignment metal strip, wherein the alignment metal strip is located at an edge of one side of the metal frame, a first align mark and a first photographing mark are provided on the alignment metal strip, and the first align mark and the first photographing mark are arranged along a direction in which the edge extends,
the metal frame is provided with a first hole, and an orthographic projection of the first photographing mark on the metal frame is located in a region where the first hole is located.

2. The metal mask according to claim 1, wherein the first hole is an inclined hole and penetrates through the metal frame, and an included angle between the inclined hole and a plane where the metal frame is located is 10-80 degrees.

3. The metal mask according to claim 1, wherein the orthographic projection of the first photographing mark on the metal frame is located in a region of a first opening of the first hole, and the first opening is an opening of the first hole on a side surface of the metal frame facing the alignment metal strip.

4. The metal mask according to claim 1 , wherein the first align mark and the first photographing mark are hollow patterns on a metal.

5. The metal mask according to claim 1 , wherein shapes of the first align mark and the first photographing mark are different, and directions, extending along the edge, of the first align mark and the first photographing mark are located on a same straight line.

6. The metal mask according to claim 1 , wherein the metal frame is further provided with a second hole, wherein the second hole is located at an orthographic projection of the first align mark on the metal frame,
the second hole is an inclined hole.

7. The metal mask according to claim 1 , wherein the first align mark and the first photographing mark each have a symmetry center and at least one symmetry axis,
a symmetry center of the first align mark is located on a straight line where a symmetry axis of the first photographing mark is located.

8. The metal mask according to claim 1 , wherein the first photographing mark is rectangular, the first align mark is circular, and the first hole is a round hole.

9. A method of evaporation using the metal mask according to claim 1 , wherein the method comprises:
moving a substrate to be evaporated above the metal mask, wherein the substrate is provided with a first substrate mark having a same shape as the first align mark of the metal mask, and a second substrate mark corresponding to the first photographing mark,
while making the first align mark align with the first substrate mark, make a position of an orthographic projection of the second substrate mark on the metal mask cover the first photographing mark, to make the metal mask and the substrate implement alignment;
evaporating a material to be evaporated on the substrate based on the aligned metal mask.

10. The method according to claim 9, wherein making the metal mask and the substrate implement alignment comprises:
capturing an image of the second substrate mark using a charge coupled device, and determining a position of the second substrate mark depending on gray tone recognition, to implement the alignment based on the second substrate mark and the first align mark.

11. A display panel, wherein the display panel is prepared using the metal mask according to claim 1 .

12. A display device, comprising the display panel according to claim 11.

13. The metal mask according to claim 2, wherein the orthographic projection of the first photographing mark on the metal frame is located in a region of a first opening of the first hole, and the first opening is an opening of the first hole on a side surface of the metal frame facing the alignment metal strip.

14. The metal mask according to claim 2, wherein the first align mark and the first photographing mark are hollow patterns on a metal.

15. The metal mask according to claim 2, wherein shapes of the first align mark and the first photographing mark are different, and directions, extending along the edge, of the first align mark and the first photographing mark are located on a same straight line.

16. The metal mask according to claim 2, wherein the metal frame is further provided with a second hole, wherein the second hole is located at an orthographic projection of the first align mark on the metal frame,
the second hole is an inclined hole.

17. The metal mask according to claim 2, wherein the first align mark and the first photographing mark each have a symmetry center and at least one symmetry axis,
a symmetry center of the first align mark is located on a straight line where a symmetry axis of the first photographing mark is located.

18. The metal mask according to claim 2, wherein the first photographing mark is rectangular, the first align mark is circular, and the first hole is a round hole.
